(19) United States
(12) Patent Application Publication
(10) Pub. No.: US 2018/0240864 A1
(43) Pub. Date: Aug. 23, 2018

(54) METHOD OF MANUFACTURING SEMICONDUCTOR DEVICE

(71) Applicant: TOYOTA JIDOSHA KABUSHIKI KAISHA, Toyota-shi (JP)

(72) Inventor: Tatsuji NAGAOKA, Nagakute-shi (JP)

(73) Assignee: TOYOTA JIDOSHA KABUSHIKI KAISHA, Toyota-shi (JP)

(21) Appl. No.: 15/866,887

(22) Filed: Jan. 10, 2018

(30) Foreign Application Priority Data
Feb. 23, 2017 (JP) 2017-032314

(51) Int. Cl. H01L 29/06; H01L 29/872; H01L 29/66; H01L 21/283; H01L 29/24

(52) U.S. Cl. CPC H01L 29/063; H01L 29/872; H01L 29/66143; H01L 21/283; H01L 29/24; H01L 29/66969

(57) ABSTRACT

A method of manufacturing a semiconductor device includes: preparing a semiconductor substrate provided with an ohmic-contact layer, a drift layer, and a high resistivity layer; forming an upper electrode having a contact area that is in contact with each of upper surfaces of the drift layer and the high resistivity layer, wherein an outer peripheral edge of the contact area is located on the high resistivity layer and the upper electrode is in Schottky contact with at least the drift layer; and forming a lower electrode being in ohmic contact with a lower surface of the ohmic-contact layer. In the semiconductor substrate, the drift layer is located on a first region of the upper surface of the ohmic-contact layer and the high resistivity layer is located on a second region of the upper surface of the ohmic-contact layer that surrounds the first region.

### TECHNICAL FIELD

The teachings disclosed herein relate to a method of manufacturing a semiconductor device.

### BACKGROUND

Japanese Patent Application Publication No. 2013-102081 describes a semiconductor device. This semiconductor device includes a semiconductor substrate, an upper electrode, and a lower electrode. The semiconductor substrate includes an ohmic contact layer, a drift layer located on the ohmic contact layer, and a high resistivity layer provided on a surface layer of the drift layer. The upper electrode is in Schottky contact with the drift layer, and the lower electrode is in ohmic contact with a lower surface of the ohmic contact layer. The upper electrode is in contact with upper surfaces of the drift layer and the high resistivity layer within a contact area, and an outer peripheral edge of this contact area is located on the high resistivity layer. According to such a structure, a depletion layer easily spreads at the outer peripheral edge of this contact area between the upper electrode and the semiconductor substrate, so breakdown voltage of the semiconductor device is improved by electric field concentration in a vicinity of the outer peripheral edge of the contact area being alleviated.

### SUMMARY

The aforementioned semiconductor device provides the high resistivity layer only on the surface of the drift layer. According to such a structure, an electric filed distribution in the drift layer interposed between the ohmic contact layer and the high resistivity layer becomes irregular, and a strong electric field may locally occur for example in a vicinity of an interface of the high resistivity layer and the drift layer. The teachings herein provide a new structure that solves this issue and that may further improve breakdown voltage of a semiconductor device, and a manufacturing method thereof.

With the structure of a semiconductor device disclosed herein, a semiconductor substrate may comprise: an n-type ohmic contact layer; an n-type drift layer located on a first region of an upper surface of an ohmic contact layer and being lower in carrier density than the ohmic contact layer; and an n-type high resistivity layer located on a second region of the upper surface of the ohmic contact layer and being lower in carrier density than the drift layer, where the second region surrounds the first region. An upper electrode contacts with upper surfaces of the drift layer and the high resistivity layer, and an outer peripheral edge of a contact area thereof is located on the high resistivity layer, and is in Schottky contact at least with the drift layer. A lower electrode is in ohmic contact with a lower surface of the ohmic contact layer.

In the above structure, the high resistivity layer exists not only on the surface of the drift layer but also extends onto the ohmic contact layer. According to this structure, irregularity in electric field distribution around the high resistivity layer occurs less, and local generation of strong electric field can be suppressed. Due to this, breakdown voltage of the semiconductor device further improves.

The teachings herein further disclose a manufacturing method of the aforementioned semiconductor device. This manufacturing method may comprise preparing a semiconductor substrate comprising: an n-type ohmic-contact layer, an n-type drift layer located on a first region of an upper surface of the ohmic-contact layer and being lower in carrier density than the ohmic-contact layer, and an n-type high resistivity layer located on a second region of the upper surface of the ohmic-contact layer, wherein the second region surrounds the first region, and the high resistivity layer is lower in carrier density than the drift layer; forming an upper electrode having a contact area that is in contact with each of upper surfaces of the drift layer and the high resistivity layer, wherein an outer peripheral edge of the contact area is located on the high resistivity layer, and the upper electrode is in Schottky contact with at least the drift layer; and forming a lower electrode being in ohmic contact with a lower surface of the ohmic-contact layer. According to this manufacturing method, the aforementioned semiconductor device with the improved breakdown voltage can be manufactured.

### BRIEF DESCRIPTION OF DRAWINGS

FIG. 1 is a plan view of a semiconductor device 10.

FIG. 2 is a cross-sectional view along a line II-II of FIG. 1, and schematically shows a structure related to breakdown voltage of the semiconductor device 10.

FIG. 3 is a flowchart showing a flow of a manufacturing method of a semiconductor device 10 of a first embodiment.

FIG. 4 is a diagram explaining a process in preparing a semiconductor substrate 12 (S12), and shows an initial state of the semiconductor substrate 12.

FIG. 5 is a diagram explaining a process in preparing the semiconductor substrate 12 (S12), and shows the semiconductor substrate 12 in which a drift layer 34 is formed.

FIG. 6 is a diagram explaining a process in preparing the semiconductor substrate 12 (S12), and shows the semiconductor substrate 12 in which the drift layer on a second region Y is removed.

FIG. 7 is a diagram explaining a process in preparing the semiconductor substrate 12 (S12), and shows the semiconductor substrate 12 in which a high resistivity layer 36 is formed by epitaxial growth.

FIG. 8 is a diagram explaining a process in preparing the semiconductor substrate 12 (S12), and shows the semiconductor substrate 12 in which an excessive portion of the high resistivity layer 36 is removed.

FIG. 9 is a diagram explaining a process in forming an insulating film 20 (S14), and shows the semiconductor substrate 12 in which the insulating film 20 is formed over an entirety of an upper surface 12a.

FIG. 10 is a diagram explaining a process in forming the insulating film 20 (S14), and shows the semiconductor substrate 12 in which the insulating film 20 is patterned.

FIG. 11 is a diagram explaining a process in forming an upper electrode 14 (S16), and shows the semiconductor substrate 12 in which the upper electrode 14 is formed over the entirety of the upper surface 12a.

FIG. 12 is a diagram explaining a process in forming the upper electrode 14 (S16), and shows the semiconductor substrate 12 in which the upper electrode 14 is patterned.

FIG. 13 is a diagram explaining a process in forming a protective film 22 (S18), and shows the semiconductor substrate 12 in which the protective film 22 is formed over the entirety of the upper surface 12a.

FIG. 14 is a diagram explaining a process in forming the protective film 22 (S18), and shows the semiconductor substrate 12 in which the protective film 22 is patterned.

FIG. 15 is a diagram explaining a process in preparing a semiconductor substrate 12 (S12) of a second embodiment, and shows the semiconductor substrate 12 in which a drift layer 34 is formed.

FIG. 16 is a diagram explaining a process in preparing the semiconductor substrate 12 (S12) of the second embodiment, and shows the semiconductor substrate 12 in which impurities are ion-implanted to the drift layer 34 on a second region Y.

FIG. 17 is a diagram explaining a process in preparing the semiconductor substrate 12 (S12) of the second embodiment, and shows the semiconductor substrate 12 in which another drift layer 34 is formed.

FIG. 18 is a diagram explaining a process in preparing the semiconductor substrate 12 (S12) of the second embodiment, and shows the semiconductor substrate 12 in which impurities are ion-implanted to the drift layer 34 on the second region Y.

FIG. 19 is a diagram explaining a process in preparing the semiconductor substrate 12 (S12) of the second embodiment, and shows the semiconductor substrate 12 in which yet another drift layer 34 is formed.

FIG. 20 is a diagram explaining a process in preparing the semiconductor substrate 12 (S12) of the second embodiment, and shows the semiconductor substrate 12 in which impurities are ion-implanted to the drift layer 34 on the second region Y.

### DETAILED DESCRIPTION

A structure and a manufacturing method of the present disclosure can be applied to a semiconductor device that uses a semiconductor in which formation of a p-type region is difficult. Generally, a guard ring structure having a p-type guard ring region is known as one of structures that can improve breakdown voltage of a semiconductor device. However, employment of the guard ring structure is difficult with a semiconductor in which a p-type region cannot easily be formed. In regard to this, the structure and the manufacturing method of the present disclosure do not require the formation of a p-type region, thus can be said as being effective for a semiconductor in which the formation of a p-type region is difficult. As a semiconductor in which the formation of a p-type region is difficult, oxide semiconductors such as gallium oxide (Ga₂O₃) may be exemplified. Especially with an oxide semiconductor in which a Conduction Band Minimum (CBM) of the oxide semiconductor is lower than −4.0 eV and a Valence Band Maximum (VBM) of the oxide semiconductor is lower than −6.0 eV with a vacuum level as a reference, the formation of the p-type region is difficult. However, the structure and the manufacturing method of the present disclosure can further be applied suitably to a semiconductor device that uses other semiconductors, for example the gallium nitride (GaN).

In an embodiment, the manufacturing method of a semiconductor device may further comprise forming an insulating film on an area of the upper surface of the high resistivity layer that surrounds the contact area, the forming of the insulating film being performed between the preparing of the substrate and the forming of the upper electrode. In this case, in the forming of the upper electrode, a part of the upper electrode may be formed on the insulating film. According to such a configuration, a part of the upper electrode faces the high resistivity layer via the insulating film, and an electric field concentration can further be alleviated by a field plate effect. That is, a part of the upper electrode can function as a field plate electrode.

In the aforementioned embodiment, the formation of the insulating film may be performed by a mist CVD (Chemical Vapor Deposition) method. When the mist CVD method is used, a raw material of the insulating film (which is for example aluminum oxide) is conveyed in a mist form, so the insulating film can be formed within a relatively short period of time.

In an embodiment, the preparing of the semiconductor substrate may comprise: forming the drift layer by epitaxial growth on the first region and the second region of the upper surface of the ohmic-contact layer; removing, by etching, a part of the drift layer located on the second region; and forming the high resistivity layer by epitaxial growth on the second region of the upper surface of the ohmic-contact layer after the drift region is removed. In this case, although it is not particularly limited, the epitaxial growth of the high resistivity layer may be performed by the mist CVD method. By using the mist CVD method, an epitaxial growth layer that is free of voids or gaps can be formed even on a non-flat surface including corners that are formed by etching.

Alternatively, in another embodiment, the preparing of the semiconductor substrate may comprise: forming the drift layer by epitaxial growth on the first region and the second region of the upper surface of the ohmic-contact layer; and performing an ion implantation of impurities to a part of the drift layer located on the second region, wherein the impurities have a property of reducing the carrier density of the part of the drift region. Due to this, a part of the drift layer formed on the second region is transformed into the high resistivity layer. Since the drift layer and the high resistivity layer are configured of a same epitaxial growth layer, foreign particles can be avoided from entering for example between the drift layer and the high resistivity layer.

In the above embodiment, the forming of the drift layer and the performing of the ion-implantation may be repeated in the preparing of the semiconductor substrate. Due to this, the drift layer and the high resistivity layer can be formed relatively thick, and the breakdown voltage of the semiconductor device can be increased.

Representative, non-limiting examples of the present invention will now be described in further detail with reference to the attached drawings. This detailed description is merely intended to teach a person of skill in the art further details for practicing preferred aspects of the present teachings and is not intended to limit the scope of the invention. Furthermore, each of the additional features and teachings disclosed below may be utilized separately or in conjunction with other features and teachings to provide improved semiconductor devices, as well as methods for using and manufacturing the same.

Moreover, combinations of features and steps disclosed in the following detailed description may not be necessary to practice the invention in the broadest sense, and are instead taught merely to particularly describe representative examples of the invention. Furthermore, various features of the above-described and below-described representative examples, as well as the various independent and dependent claims, may be combined in ways that are not specifically and explicitly enumerated in order to provide additional useful embodiments of the present teachings.

All features disclosed in the description and/or the claims are intended to be disclosed separately and independently from each other for the purpose of original written disclosure, as well as for the purpose of restricting the claimed subject matter, independent of the compositions of the features in the embodiments and/or the claims. In addition, all value ranges or indications of groups of entities are intended to disclose every possible intermediate value or intermediate entity for the purpose of original written disclosure, as well as for the purpose of restricting the claimed subject matter.

### First Embodiment

A semiconductor device 10 and a manufacturing method thereof of a first embodiment will be described with reference to the drawings. The semiconductor device 10 is one type of power semiconductor device, and can be employed in a circuit for supplying power to a motor that drives wheels in an electrically-driven vehicle such as an electric vehicle, a hybrid vehicle, and a fuel cell vehicle. It should be noted that technical elements disclosed in this embodiment are not limited to the semiconductor device 10 and the manufacturing method thereof, and they may be applied to various other semiconductor devices and manufacturing methods thereof. Hereinbelow, a configuration of the semiconductor device 10 will be described first, and then the manufacturing method of the semiconductor device 10 will be described.

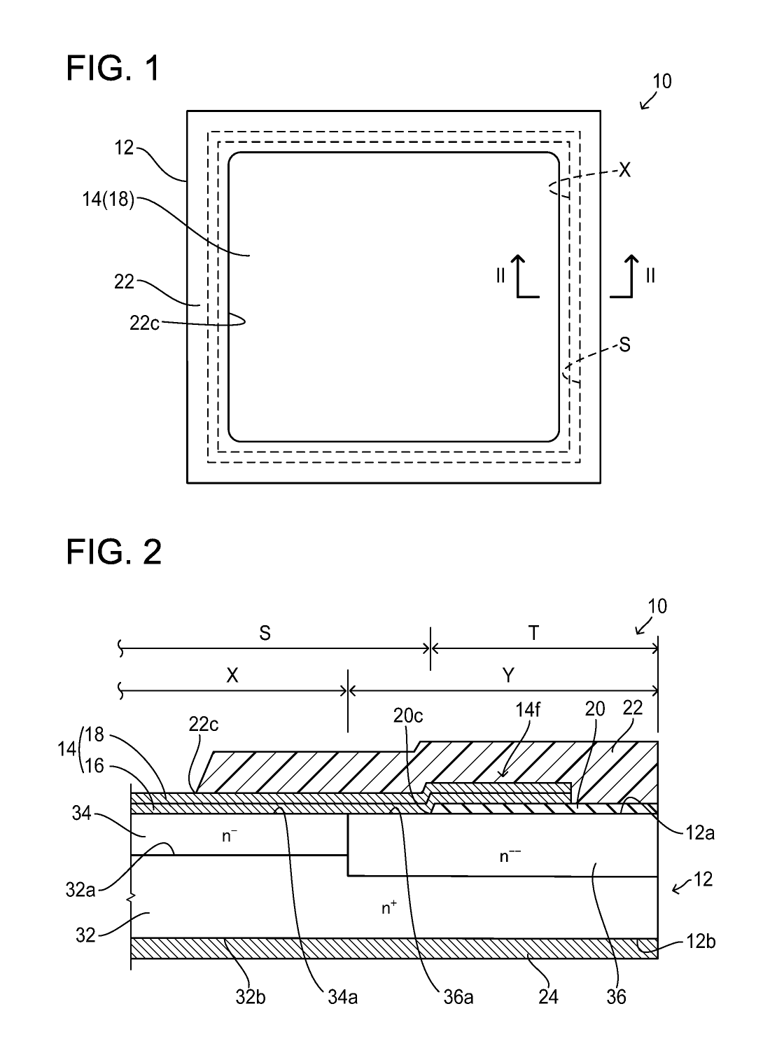

As shown in FIGS. 1 and 2, the semiconductor device 10 includes a semiconductor substrate 12, an upper electrode 14, an insulating film 20, a protective film 22, and a lower electrode 24. The upper electrode 14, the insulating film 20, and the protective film 22 are provided on an upper surface 12a of the semiconductor substrate 12, and the lower electrode 24 is provided on a lower surface 12b of the semiconductor substrate 12. An outer circumferential portion 14f of the upper electrode 14 faces the semiconductor substrate 12 via the insulating film 20, and functions as a field plate electrode.

The semiconductor substrate 12 is an n-type semiconductor substrate. The semiconductor substrate 12 of the present embodiment is, although it is not particularly limited, a gallium oxide (Ga₂O₃) substrate. The semiconductor substrate 12 includes an n-type ohmic contact layer 32, a drift layer 34 having lower carrier density than the ohmic contact layer 32, and a high resistivity layer 36 having lower carrier density than the drift layer 34. The ohmic contact layer 32 is located as a lower layer of the semiconductor substrate 12, and constitutes the lower surface 12b of the semiconductor substrate 12. The drift layer 34 and the high resistivity layer 36 are provided on the ohmic contact layer 32, and constitute the upper surface 12a of the semiconductor substrate 12.

Specifically, the drift layer 34 is provided on a first region X of an upper surface 32a of the ohmic contact layer 32, and extends to the upper surface 12a of the semiconductor substrate 12. The high resistivity layer 36 is provided on a second region Y of the upper surface 32a of the ohmic contact layer 32, and extends to the upper surface 12a of the semiconductor substrate 12. In a plan view, the first region X is located at a center portion of the semiconductor substrate 12, the second region Y is located at a peripheral portion of the semiconductor substrate 12, and the first region X is surrounded by the second region Y. That is, the drift layer 34 is surrounded by the high resistivity layer 36. In this embodiment, the upper surface 32a of the ohmic contact layer 32 includes a level difference at a boundary between its first region X and second region Y, however, such a level difference is not mandatory.

The upper electrode 14 is in contact with both the drift layer 34 and the high resistivity layer 36 at the upper surface 12a of the semiconductor substrate 12, and outer peripheral edges of a contact area S thereof is located on the high resistivity layer 36. That is, the contact area S between the upper electrode 14 and the semiconductor substrate 12 includes an upper surface 34a of the drift layer 34 and an upper surface 36a of the high resistivity layer 36, and the upper surface 34a of the drift layer 34 is surrounded by the upper surface 36a of the high resistivity layer 36. The upper electrode 14 is in Schottky contact with at least the upper surface 34a of the drift layer 34. Although this is merely an example, the upper electrode 14 includes a Schottky electrode 16 and a contact electrode 18. The contact electrode 18 is provided on the Schottky electrode 16, and is electrically connected to the Schottky electrode 16. A material of the Schottky electrode 16 simply needs to be a conductive material capable of making a Schottky contact with the drift layer 34, and it is not particularly limited, however, it may for example be platinum (Pt). On the other hand, a material of the contact electrode 18 simply needs to be a conductive material, and is not particularly limited, however, it may for example be gold (Au). Alternatively, the contact electrode 18 may have a laminate structure including layers of titanium (Ti), nickel (Ni), and gold.

The insulating film 20 is provided on the high resistivity layer 36, and extends annularly along edges of the semiconductor substrate 12. Specifically, within the upper surface 36a of the high resistivity layer 36, the insulating film 20 is provided in an area T that surrounds the aforementioned contact area S. That is, inner peripheral edges 20c of the insulating film 20 are the outer peripheral edges of the contact area S between the semiconductor substrate 12 and the upper electrode 14. As aforementioned, the field plate electrode 14f, which is the outer peripheral portion of the upper electrode 14, is located on the insulating film 20, and faces the semiconductor substrate 12 via the insulating film 20. More specifically, the field plate electrode 14f faces the high resistivity layer 36 via the insulating film 20. A material of the insulating film 20 simply needs to be a material having desired insulation property, and thus is not particularly limited, however, it may for example be aluminum oxide (Al₂O₃).

The protective film 22 extends annularly along the periphery of semiconductor substrate 12, and covers the outer peripheral portion of the upper electrode 14 including the field plate electrode 14f and also covers the insulating film 20. Inner peripheral edges 22c of the protective film 22 define an opening through which the upper electrode 14 can be exposed. A material of the protective film 22 simply needs to be an insulative material, and it is not particularly limited, however, it may for example be a polymer material such as polyimide.

The lower electrode 24 is in ohmic contact with a lower surface 32b of the ohmic contact layer 32 at the lower surface 12b of the semiconductor substrate 12. A material of the lower electrode 24 simply needs to be a material that can make ohmic contact with the ohmic contact layer 32, and thus is not particularly limited. The lower electrode 24 of this embodiment makes contact with the entirety of the lower surface 12b of the semiconductor substrate 12, however, as another embodiment, the lower electrode 24 may make contact with only a part of the lower surface 12b of the semiconductor substrate 12.

According to the aforementioned structure, the semiconductor device 10 of this embodiment embodies a Schottky barrier diode (which will hereafter be referred simply as “diode”) that uses the upper electrode 14 as an anode and the lower electrode 24 as a cathode. In this diode, the outer peripheral edges of the contact area S between the semiconductor substrate 12 and the upper electrode 14 are located on the high resistivity layer 36. Since the high resistivity layer 36 has lower carrier density than the drift layer 34, a depletion layer easily spreads in the high resistivity layer 36 when an inversed bias voltage is applied between the semiconductor substrate 12 and the upper electrode 14. In addition, the high resistivity layer 36 extends to the ohmic contact layer 32. According to such a structure, irregularity in electric field distribution around the high resistivity layer 36 occurs less as compared to a structure in which the drift layer 34 is interposed between the high resistivity layer 36 and the ohmic contact layer 32, and local generation of strong electric field can be suppressed. Due to this, breakdown voltage of the semiconductor device 10 further improves.

In addition, the semiconductor device 10 includes the field plate electrode 14f. The field plate electrode 14f faces the high resistivity layer 36 of the semiconductor substrate 12 via the insulating film 20. According to such a structure, the depletion layer easily spreads by field plate effect, and the electric field concentration in the outer peripheral edges of the contact area S is further alleviated.

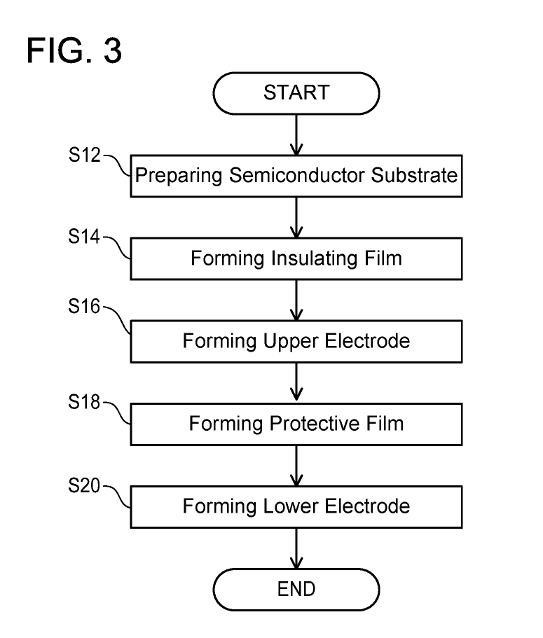

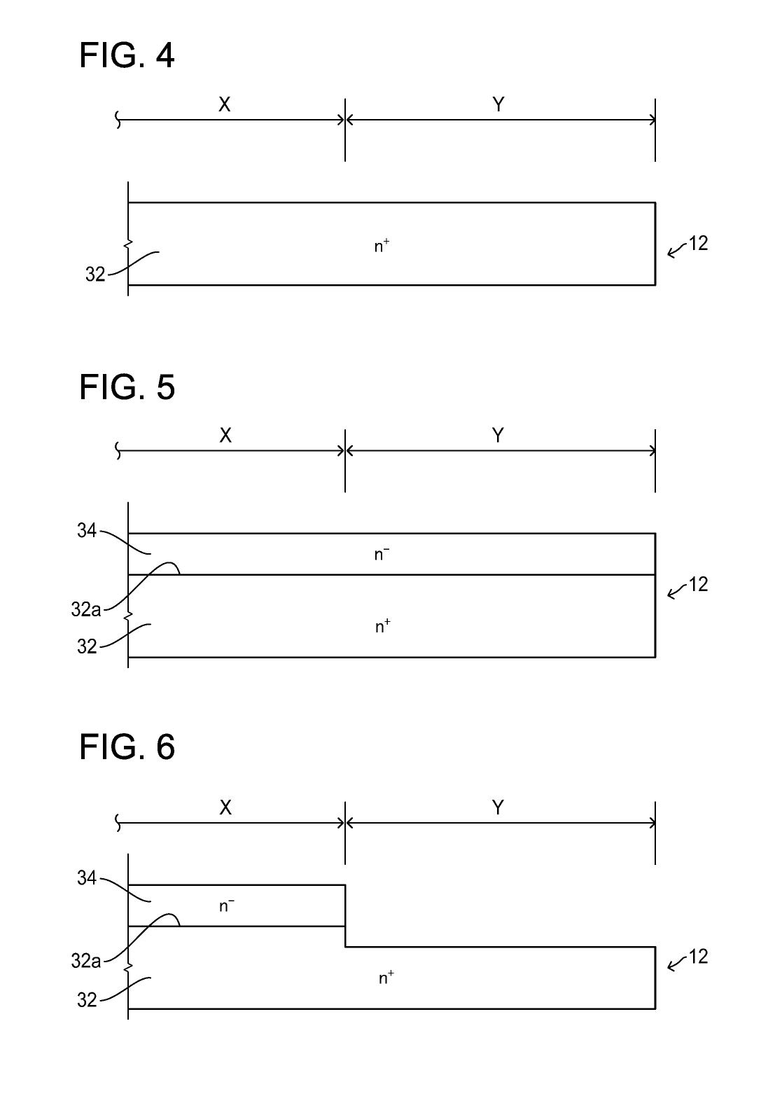

Next, a manufacturing method of the semiconductor device 10 will be described. FIG. 3 is a flow chart showing a flow of the manufacturing method of the present embodiment. Firstly, in step S12, a semiconductor substrate 12 is prepared. In this step, although not particularly limited, the semiconductor substrate 12 provided with an ohmic contact layer 32, a drift layer 34, and a high resistivity layer 36 as shown in FIG. 8 is prepared according to processes shown in FIGS. 4 to 8. In this semiconductor substrate 12, the drift layer 34 is located on a first region X of an upper surface 32a of the ohmic contact layer 32, and the high resistivity layer 36 is located on a second region Y of the upper surface 32a of the ohmic contact layer 32, and in this configuration, the second region Y surrounds the first region X. Both the drift layer 34 and the high resistivity layer 36 make direct contact with the upper surface 32a of the ohmic contact layer 32, and no drift layer 34 is interposed between the ohmic contact layer 32 and the high resistivity layer 36.

Firstly, as shown in FIG. 4, the semiconductor substrate 12 that only includes the ohmic contact layer 32 is prepared. As aforementioned, the semiconductor substrate 12 may be a gallium oxide substrate. Washing and other processes are performed on the semiconductor substrate 12 as needed. Next, as shown in FIG. 5, the drift layer 34 is formed on the ohmic contact layer 32. The drift layer 34 is formed over an entirety of the ohmic contact layer 32. That is, the drift layer 34 is formed not only on the first region X but also on the second region Y. This drift layer 34 is not particularly limited, but may be formed by epitaxially growing gallium oxide. This epitaxial growth may be performed for example by an MOCVD (Metal Organic Chemical Vapor Deposition) method or an HVPE (Hydride Vapor Phase Epitaxy) method. Alternatively, the epitaxial growth of the drift layer 34 may be performed by a mist CVD method.

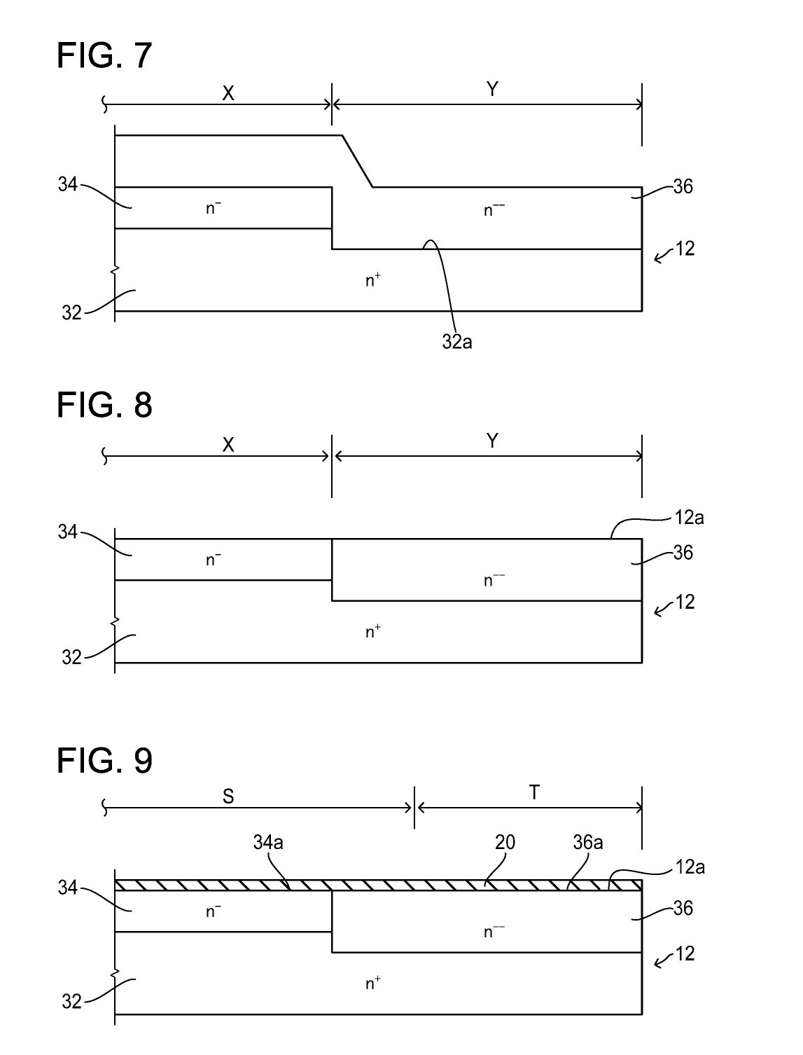

Next, as shown in FIG. 6, a part of the drift layer 34 that is formed on the second region Y is removed by etching. Due to this, the upper surface 32a of the ohmic contact layer 32 is exposed in the second region Y. Then, as shown in FIG. 7, the high resistivity layer 36 is formed on the second region Y of the upper surface 32a of the ohmic contact layer 32. At this stage, the high resistivity layer 36 may be formed over the entirety of an upper surface 12a of the semiconductor substrate 12 including an area on the drift layer 34. The formation of the high resistivity layer 36 may be performed by epitaxial growth of gallium oxide. Although it is not particularly limited, this epitaxial growth may be performed by the mist CVD method. When the mist CVD method is used, a raw material thereof (which is herein gallium oxide) is conveyed in a mist form, so an epitaxial growth layer that is free of voids can be formed within a short period of time even on the semiconductor substrate 12 that has a level difference formed by the previously-performed etching.

In the epitaxial growth of the high resistivity layer 36, as compared to the epitaxial growth of the drift layer 34, impurities of iron (Fe) and/or magnesium (Mg) may preferably be added. Addition of these impurities suppresses the carrier density of the high resistivity layer 36 lower than that of the drift layer 34, and resistivity thereof increases. It should be noted that the impurities are not limited to certain types of substances, and they may be any substance that may suppress the carrier density of the n-type drift layer 34 low. Alternatively, a concentration of the n-type impurities to be added may simply be lowered. Next, as shown in FIG. 8, excessive high resistivity layer 36 is removed to planarize the upper surface 12a of the semiconductor substrate 12. Although it is not particularly limited, this planarizing can be performed by a CMP (Chemical Mechanical Polishing) method. The planarized upper surface 12a of the semiconductor substrate 12 has the drift layer 34 and the high resistivity layer 36 exposed thereon, and the high resistivity layer 36 surrounds the drift layer 34. According to the above, the semiconductor substrate 12 including the ohmic contact layer 32, the drift layer 34, and the high resistivity layer 36 is prepared.

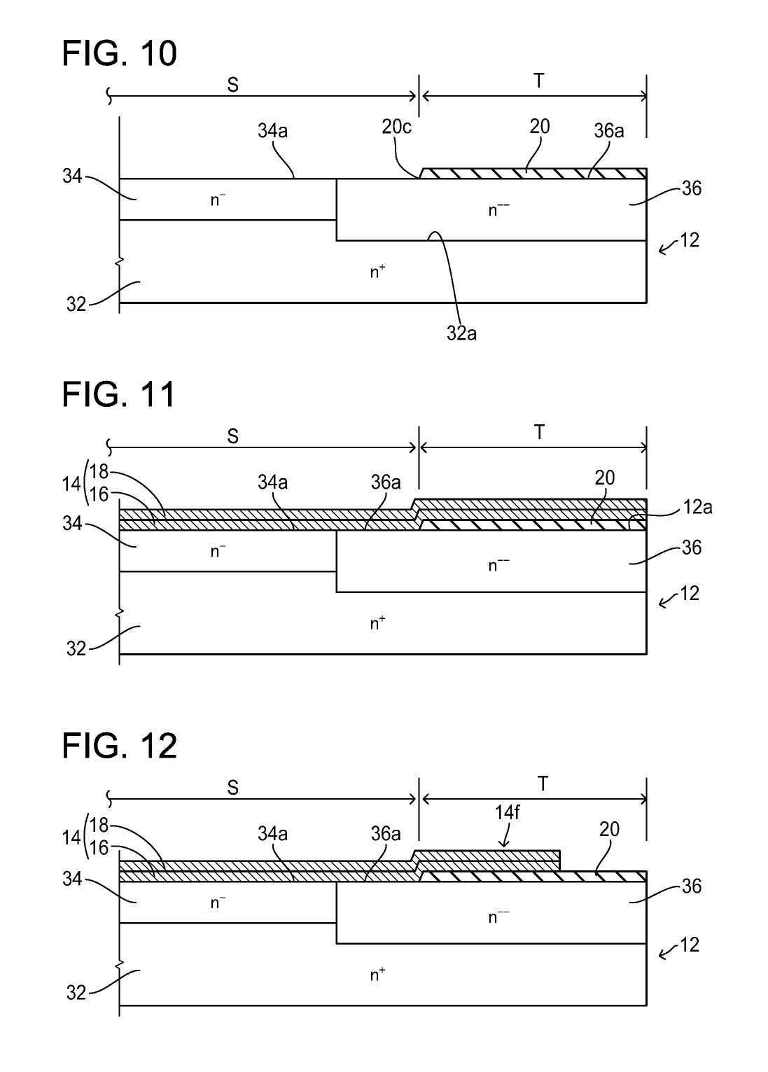

Returning to FIG. 3, in step S14, an insulating film 20 is formed on the upper surface 12a of the semiconductor substrate 12. The formation of the insulating film 20 is not particularly limited, however, it may be performed by processes shown in FIGS. 9 and 10. Firstly, as shown in FIG. 9, the insulating film 20 is formed over the entirety of the upper surface 12a of the semiconductor substrate 12. That is, the insulating film 20 is formed on both the aforementioned contact area S and the area T that surrounds the contact area S (see FIG. 2). The formation of the insulating film 20 may for example be performed by a mist CVD method.

According to the mist CVD method, the material of the insulating film 20 (for example, aluminum oxide) is conveyed in a mist form, so the insulating film 20 that is free of voids can be formed within a short period of time. Then, as shown in FIG. 10, a central portion of the insulating film 20 located on the contact area S is removed by etching to pattern the insulating film 20 in an annular shape. Due to this, the insulating film 20 is given an opening through which the drift layer 34 and the high resistivity layer 36 of the semiconductor substrate 12 can be exposed.

In step S16 of FIG. 3, an upper electrode 14 is formed on the upper surface 12a of the semiconductor substrate 12. The formation of the upper electrode 14 is not particularly limited, however, it may be performed by processes shown in FIGS. 11 and 12. Firstly, as shown in FIG. 11, the upper electrode 14 is formed over the entirety of the upper surface 12a of the semiconductor substrate 12. That is, the upper electrode 14 makes contact with the drift layer 34, the high resistivity layer 36, and the insulating film 20. As aforementioned, the upper electrode 14 of the present embodiment includes a Schottky electrode 16 and a contact electrode 18. In this case, the Schottky electrode 16 is formed first, and the contact electrode 18 is formed thereon. Although this is merely an example, a material of the Schottky electrode 16 may be platinum, and a material of the contact electrode 18 may be gold. Next, as shown in FIG. 12, an outer peripheral portion of the upper electrode 14 is removed by etching to pattern the upper electrode 14 into a desired shape. A part of the upper electrode 14 is thereby located on the insulating film 20, and functions as a field plate electrode 14f.

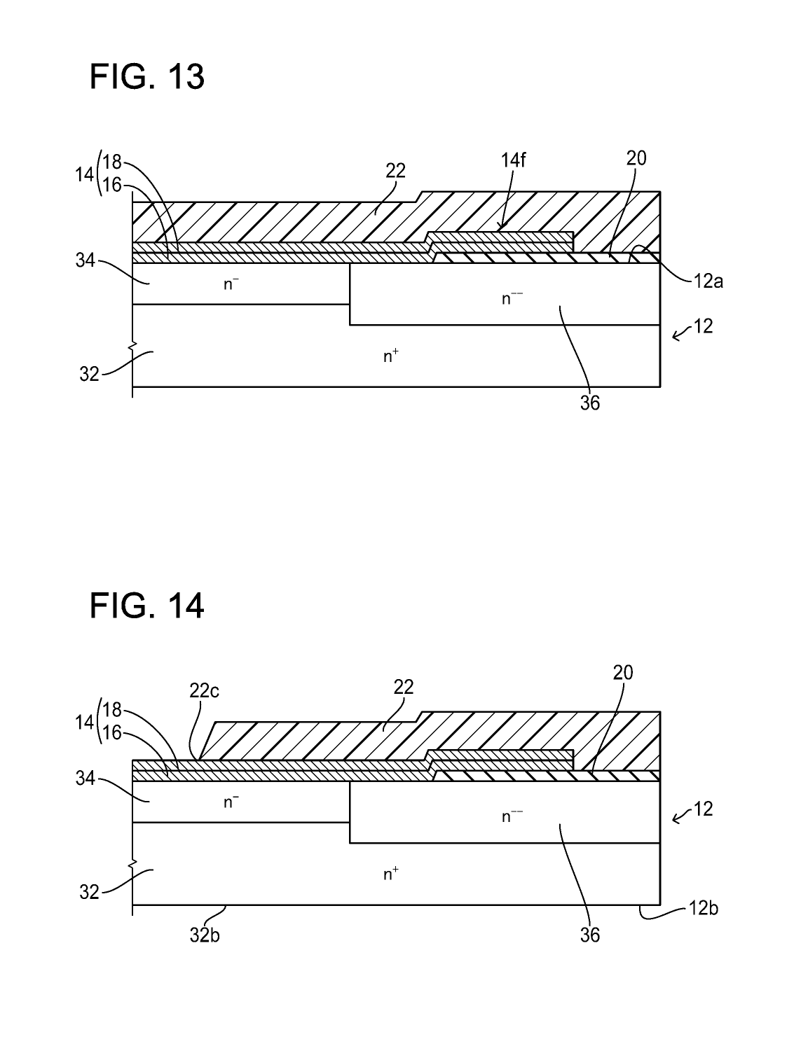

In step S18 of FIG. 3, a protective film 22 is formed on the upper surface 12a of the semiconductor substrate 12. The formation of the protective film 22 is not particularly limited, however, it may be performed by processes shown in FIGS. 13 and 14. Firstly, as shown in FIG. 13, the protective film 22 is formed over the entirety of the upper surface 12a of the semiconductor substrate 12. As aforementioned, the material of the protective film 22 is the insulative material, and may for example be polyimide. Then, as shown in FIG. 14, a central portion of the protective film 22 is removed by etching. Due to this, the protective film 22 is patterned into an annular shape, and the inner peripheral edges 22c of the protective film 22 define an opening through which the upper electrode 14 can be exposed.

In step S20 of FIG. 3, a lower electrode 24 is formed on a lower surface 12b of the semiconductor substrate 12. Due to this, the structure of the semiconductor device 10 shown in FIGS. 1 and 2 is completed. Normally, a plurality of semiconductor devices 10 is simultaneously manufactured on one piece of semiconductor wafer, and dicing to separate the semiconductor wafer into the plurality of semiconductor devices 10 is performed.

The structure of the semiconductor device 10 and the manufacturing method thereof as described in this embodiment are not limited to a semiconductor device of gallium oxide, and they may suitably be applied to semiconductor devices that use other types of semiconductor materials. It should be noted that, gallium oxide is known as a substance in which a p-type region cannot easily be formed, so it is difficult to employ a guard ring structure that requires a p-type guard ring region in the semiconductor device 10 that uses the gallium oxide semiconductor substrate 12. In this regard, according to the structure and the manufacturing method of the present embodiment, the breakdown voltage of the semiconductor device 10 can be improved without the formation of the p-type region. Thus, the structure and the manufacturing method of the present embodiment can suitably be employed especially in a semiconductor device that uses a semiconductor material with which the formation of the p-type region is difficult. As such semiconductor materials, oxide semiconductors in which a Conduction Band Minimum (CBM) is lower than −4.0 eV and a Valence Band Maximum (VBM) is lower than −6.0 eV with a vacuum level as a reference may be exemplified.

### Second Embodiment

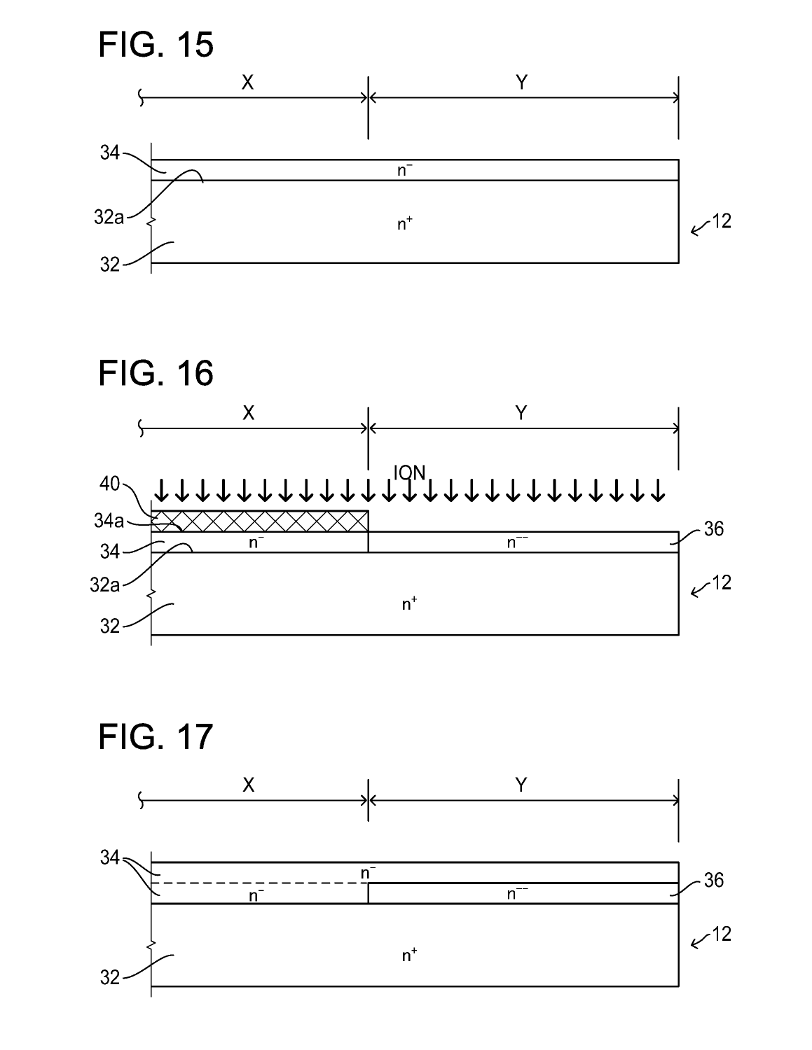

Another embodiment of a manufacturing method of a semiconductor device 10 will be described. As compared to the manufacturing method described in the first embodiment, the manufacturing method of the present embodiment differs in its procedure for preparing a semiconductor substrate 12 (S12 of FIG. 3). That is, in this embodiment, a semiconductor substrate 12 that includes an ohmic contact layer 32, a drift layer 34, and a high resistivity layer 36 is prepared by procedures of FIGS. 15 to 20 instead of the procedures shown in FIGS. 5 to 8. Other procedures are similar to those of the first embodiment, thus redundant description thereof will be omitted.

Firstly, as shown in FIG. 15, the semiconductor substrate 12 that only includes the ohmic contact layer 32 is prepared, and the drift layer 34 is formed on an upper surface 32a of the ohmic contact layer 32. The drift layer 34 is formed over an entirety of the ohmic contact layer 32. That is, the drift layer 34 is formed not only on a first region X of the upper surface 32a of the ohmic contact layer 32 but also on a second region Y thereof. As will be described later, in the manufacturing method of the present embodiment, the formation of the drift layer 34 will be performed in multiple steps. Thus, a thickness of the drift layer 34 at this stage is thinner than a thickness of the drift layer 34 that is required as a completed layer. The formation of this drift layer 34 is not particularly limited, but may be performed by epitaxially growing of gallium oxide. Further, similar to the first embodiment, this epitaxial growth may be performed for example by the MOCVD method, the HVPE method, or the mist CVD method.

Next, as shown in FIG. 16, impurities that suppress carrier density are implanted to a part of the drift layer 34 formed on the second region Y. A plurality of arrows ION in the drawing schematically shows ion implantation of the impurities. The impurities to be implanted are impurities that suppresses the carrier density in the n-type drift layer 34, and they are for example iron (Fe) and/or magnesium (Mg) as explained earlier in the first embodiment. In this ion implantation, a resist mask 40 may temporarily be formed on an upper surface 34a of the drift layer 34 located on a first region X so that the impurities are not introduced into the drift layer 34 on the first region X. By so doing, the upper surface 32a of the ohmic contact layer 32 comes to have the drift layer 34 located on the first region X, and the high resistivity layer 36 located on the second region Y formed thereon.

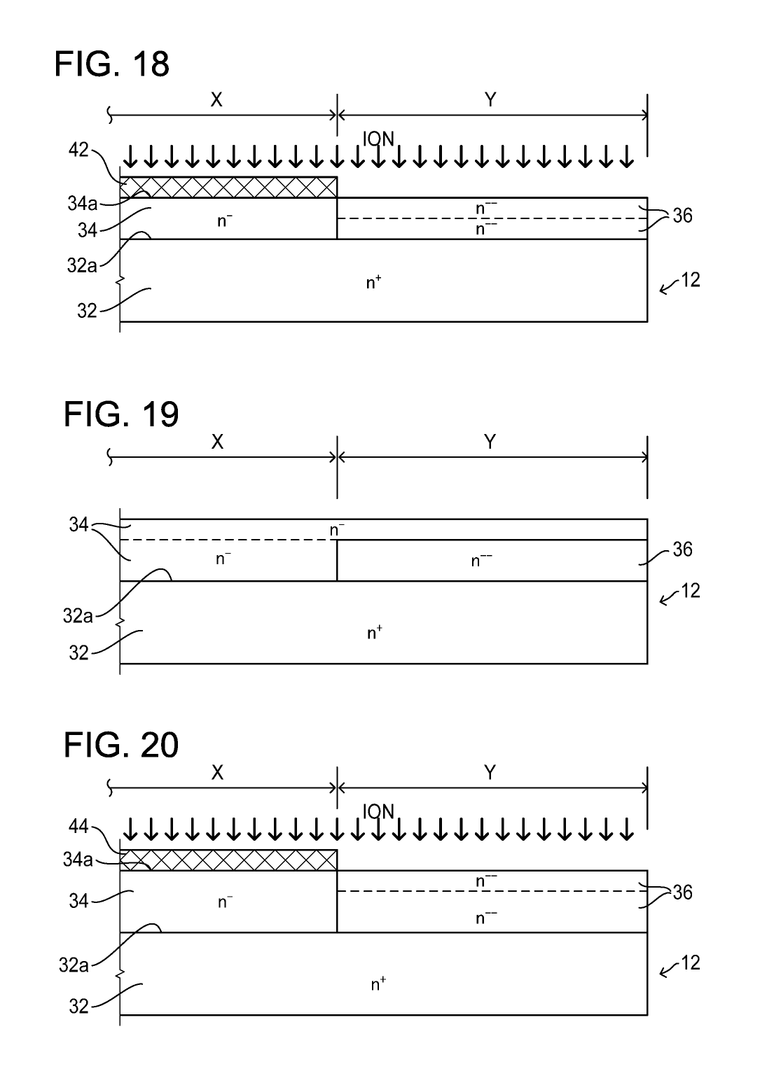

Next, as shown in FIG. 17, a new drift layer 34 is formed on the existing drift layer 34 and the high resistivity layer 36. This drift layer 34 is similarly formed over both the first region X and the second region Y. Then, as shown in FIG. 18, the impurities that suppress the carrier density are implanted to a part of this drift layer 34 formed on the second region Y. In this ion implantation as well, a resist mask 42 may temporarily be formed on an upper surface 34a of the drift layer 34 located on the first region X so that the impurities are not introduced into the drift layer 34 on the first region X. By so doing, a thicker drift layer 34 is formed on the first region X, and a thicker high resistivity layer 36 is formed on the second region Y.

Next, as shown in FIG. 19, a yet another drift layer 34 is formed on the existing drift layer 34 and the high resistivity layer 36. This drift layer 34 is similarly formed over both the first region X and the second region Y. Then, as shown in FIG. 20, the impurities that suppress the carrier density are implanted to a part of this drift layer 34 formed on the second region Y. In this ion implantation as well, a resist mask 44 may temporarily be formed on an upper surface 34a of the drift layer 34 located on the first region X so that the impurities are not introduced into the drift layer 34 on the first region X. By so doing, an even thicker drift layer 34 is formed on the first region X, and an even thicker high resistivity layer 36 is formed on the second region Y. According to the above procedures, the semiconductor substrate 12 including the ohmic contact layer 32, the drift layer 34, and the high resistivity layer 36 is prepared.

In the manufacturing method of this embodiment, the formation of the drift layer 34 and the ion implantation of the impurities are repeated to prepare the semiconductor substrate 12. Due to this, both the drift layer 34 and the high resistivity layer 36 can be formed thick, and the breakdown voltage of the semiconductor device 10 can be improved. A number of times that the formation of the drift layer 34 and the ion implantation of the impurities are repeated is not particularly limited. For example, the number of cycles to be repeated may be determined according to the thicknesses required for the drift layer 34 and the high resistivity layer 36. In another embodiment, the formation of the drift layer 34 and the ion implantation of the impurities may each be performed just once, and the cycle thereof may not be repeated.

What is claimed is:

1. A method of manufacturing a semiconductor device, the method comprising:
preparing a semiconductor substrate comprising:
an n-type ohmic-contact layer,
an n-type drift layer located on a first region of an upper surface of the ohmic-contact layer and being lower in carrier density than the ohmic-contact layer, and
an n-type high resistivity layer located on a second region of the upper surface of the ohmic-contact layer, wherein the second region surrounds the first region, and the high resistivity layer is lower in carrier density than the drift layer;
forming an upper electrode having a contact area that is in contact with each of upper surfaces of the drift layer and the high resistivity layer, wherein an outer peripheral edge of the contact area is located on the high resistivity layer, and the upper electrode is in Schottky contact with at least the drift layer; and
forming a lower electrode being in ohmic contact with a lower surface of the ohmic-contact layer.

2. The method according to claim 1, wherein
the semiconductor substrate is a substrate of oxide semiconductor, and
with a vacuum level as a reference, a Conduction Band Minimum (CBM) of the oxide semiconductor is lower than −4.0 eV and a Valence Band Maximum (VBM) of the oxide semiconductor is lower than −6.0 eV.

3. The method according to claim 1, wherein the semiconductor substrate is a substrate of gallium oxide.

4. The method according to claim 1, further comprising:
forming an insulating film on an area of the upper surface of the high resistivity layer that surrounds the contact area, the forming of the insulating film being performed between the preparing of the substrate and the forming of the upper electrode,
wherein, in the forming of the upper electrode, a part of the upper electrode is formed on the insulating film.

5. The method according to claim 4, wherein the forming of the insulating film is performed by a mist CVD method.

6. The method according to claim 1, wherein the preparing of the semiconductor substrate comprises:
forming the drift layer by epitaxial growth on the first region and the second region of the upper surface of the ohmic-contact layer;
removing, by etching, a part of the drift layer located on the second region; and
forming the high resistivity layer by epitaxial growth on the second region of the upper surface of the ohmic-contact layer after the drift region is removed.

7. The method according to claim 6, wherein the epitaxial growth of the high resistivity layer is performed by a mist CVD method.

8. The method according to claim 1, wherein the preparing of the semiconductor substrate comprises:
forming the drift layer by epitaxial growth on the first region and the second region of the upper surface of the ohmic-contact layer; and
performing an ion implantation of impurities to a part of the drift layer located on the second region, wherein the impurities have a property of reducing the carrier density of the part of the drift region.

9. The method according to claim 8, wherein the forming of the drift layer and the performing of the ion-implantation are repeated in the preparing of the semiconductor substrate.
